(19) United States
(12) Patent Application Publication
(10) Pub. No.: US 2006/0256526 A1
(43) Pub. Date: Nov. 16, 2006

(54) Liquid cooling system

(75) Inventor: Brian A. Hamman, Krugerville, TX (US)

Correspondence Address: Arthur W. Fisher;Patent Dominion LP, Suite 200, 555 Republic Drive, Plano, TX, 75074, US

(73) Assignee: QNX Cooling Systems Inc.

(21) Appl. No.: 11/486,943

(22) Filed: Jul. 17, 2006

Related U.S. Application Data
(63) Continuation of application No. 10/964,344, filed on Oct. 13, 2004.

(51) Int. Cl. H05K 7/20; F25D 23/12

(52) U.S. Cl. 361/699; 62/259.2

(57) ABSTRACT

Liquid cooling systems and apparatus and data processing systems and communication systems with liquid cooling systems are presented. A number of embodiments are presented. An embodiment is disclosed for data processing systems and communication systems having rack mounted sub-assemblies which can be inserted into or retracted from a rack or other holding device (and even while the data processing system or the communication system is operating) wherein the liquid communication to the heat transfer systems on a sub-assembly may be switched on or off.

### CROSS REFERENCE TO RELATED APPLICATIONS

The present application is a continuation application of application Ser. No. 10/964,344 filed on Oct. 13, 2004 entitled “Liquid Cooling System” which is incorporated herein by reference. The priority date of application Ser. No. 10/964,344 is claimed. Reference is also made to U.S. patent application Ser. No. 11/361,943 entitled Cooling System and filed on Feb. 27, 2006.

### BACKGROUND OF THE INVENTION

Description of the Related Art

Paragraphs [0002] through [0004] of application Ser. No. 10/964,344 are incorporated here by reference.

A number of approaches have been implemented to address processor heating. Initial approaches focused on air-cooling. These techniques may be separated into three categories: 1) cooling techniques which focused on cooling the air outside of the computing system; 2) cooling techniques that focused on cooling the air inside the computing system; and 3) a combination of the cooling techniques (i.e., 1 and 2).

Many of these conventional approaches are elaborate and costly. For example, one approach for cooling air outside of the computing system involves the use of a cold room. A cold room is typically implemented in a specially constructed data center, which includes air conditioning units, specialized flooring, walls, etc., to generate and retain as much cooled air within the cold room as possible.

Cold rooms are very costly to build and operate. The specialized buildings, walls, flooring, air conditioning systems, and the power to run the air conditioning systems all add to the cost of building and operating the cold room. In addition, an elaborate ventilation system is typically also implemented and in some cases additional cooling systems may be installed in floors and ceilings to circulate a high volume of air through the cold room. Further, in these cold rooms, computing equipment is typically installed in specialized racks to facilitate the flow of cooled air around and through the computing system. However, with decreasing profit margins in many industries, operators are not willing to incur the expenses associated with operating a cold room. In addition, as computing systems are implemented in small companies and in homes, end users are unable and unwilling to incur the cost associated with the cold room, which makes the cold room impractical for this type of user.

The second type of conventional cooling technique focused on cooling the air surrounding the processor. This approach focused on cooling the air within the computing system. Examples of this approach include implementing simple ventilation holes or slots in the chassis of a computing system, deploying a fan within the chassis of the computing system, etc. However, as processors become more densely populated with circuitry and as the number of processors implemented in a computing system increases, cooling the air within the computing system can no longer dissipate the necessary amount of heat from the processor or the chassis of a computing system.

Conventional techniques also involve a combination of cooling the air outside of the computing system and cooling the air inside the computing system. However, as with the previous techniques, this approach is also limited. The heat produced by processors has quickly exceeded beyond the levels that can be cooled using a combination of the air-cooling techniques mentioned above.

Paragraphs [0010] through [0015] of application Ser. No. 10/964,344 are incorporated here by reference.

Thus, there is a need in the art for a method and apparatus for cooling computing systems. There is a need in the art for a method and apparatus for cooling processors deployed within a computing system. There is a need in the art for an optimal, cost-effective method and apparatus for cooling processors, which also allows the processor to operate at the marketed operating capacity. There is a need for a method or apparatus used to dissipate processor heat which can be deployed within the small footprint available in the case or housing of a computing system, such as a laptop computer, standalone computer, cellular telephone, etc.

### SUMMARY OF THE INVENTION

Paragraphs [0017] through [0025] of application Ser. No. 10/964,344 are incorporated here by reference.

In another embodiment the liquid cooling system is arranged such that one or more heat transfer systems have an interconnect system for enabling or disabling liquid communication with a heat exchange system and the heat transfer system(s) are liquidly connected in parallel, in series or in a combination of parallel and serial.

Paragraphs [0027] of application Ser. No. 10/964,344 is incorporated here by reference.

### BRIEF DESCRIPTION OF THE DRAWINGS

Paragraphs [0028] through [0064] of application Ser. No. 10/964,344 are incorporated here by reference.

FIG. 24 displays a rack mountable data processing system or communication system such as a blade server, for example, and having a liquid cooling system with at least one heat exchange system and a plurality of heat transfer systems disposed on heat generating components on cards that are inserted into and removed from the rack, the heat transfer systems being liquidly connected in parallel, in series and/or in a combination of parallel and series and further having interconnect systems for enabling or disabling the flow of cooled liquid to the heat transfer systems on a card and heated liquid from the heat transfer systems.

### DETAILED DESCRIPTION

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

Paragraphs [0067] through [0265] of application Ser. No. 10/964,344 are incorporated here by reference.

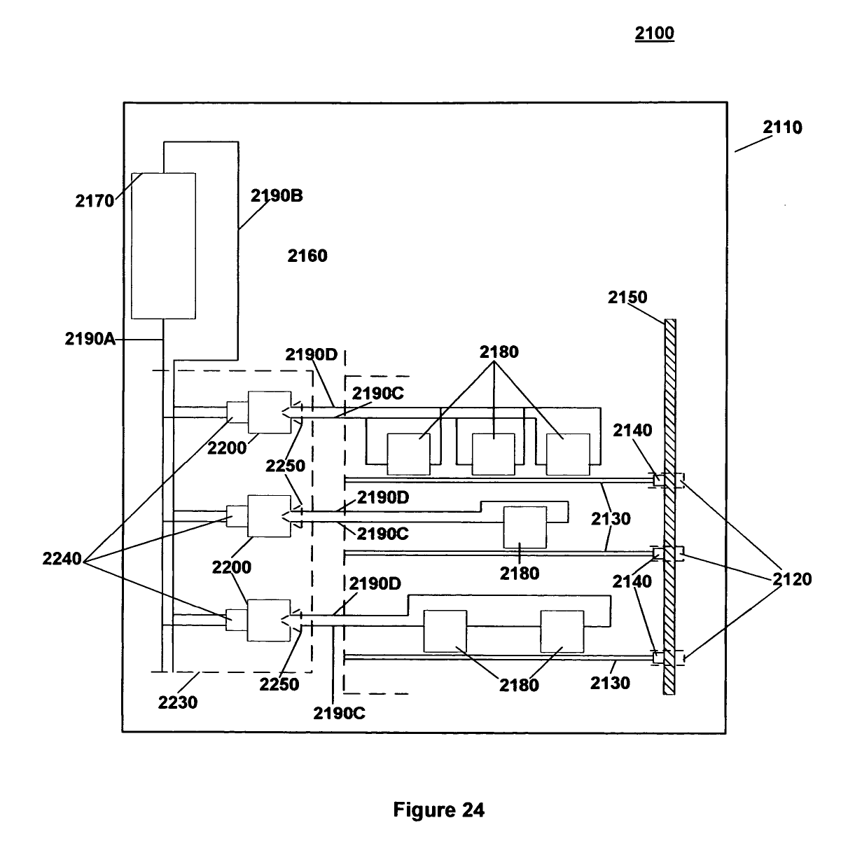

FIG. 24 comprises a side sectional view of a rack mountable data processing system or communication system 2100 such as a blade server or the like with a block schematic representation of a liquid cooling system 2160. A blade server comprises a chassis having a number of bays into which separate server cards or blades can be inserted for connection to a mid or back plane. Each server blade comprises its own storage, memory, processor and controller chips but shares power, floppy drives, switches, ports and other connections with other blade servers mountable within the chassis. In the embodiment depicted by FIG. 23, the system 2100 comprises a chassis 2110 providing a plurality of bays or slots 2120 for accommodating cards such as telecommunication line cards, for example, or server blades 2130 or the like. Each bay 2120 has a connector 2140 at the rear of the chassis for plugging the card 2130 into a back plane 2150 in a known manner.

The liquid cooling system 2160 may comprise a cooling system of any of the types described with respect to FIGS. I to 5 incorporating heat transfer systems of any of the types described with respect to FIGS. 6 to 19. The liquid cooling system may also be of an arrangement similar to those described with respect to any of FIGS. 20 to 23. The liquid cooling system 2160 comprises at least one heat exchange system 2170 and a plurality of heat transfer systems 2180, the heat transfer systems 2180 being associated with respective heat generating components (not shown) on at least one or more of the cards 2130. The heat exchange system 2170 is connected to the plurality of heat transfer systems 2180 by a liquid transport system 2190 which conveys cooled liquid from the heat exchange system 2170 towards the heat transfer systems 2180 and conveys heated liquid from the heat transfer systems 2180 towards the heat exchange system 2170 for removal of thermal energy from such heated liquid to provide a supply of cooling liquid for the system 2160.

The liquid transport system 2190 comprises a first conduit 2190A for conveying cooling liquid towards the heat transfer systems 2180 on the card(s) 2130 and a second conduit 2190B for collecting heated liquid from the heat transfer systems 2180 and conveying it towards the heat exchange system 2170 for cooling. The heat transfer systems 2180 may be arranged in series, in parallel or a combination of series and parallel on the cards 2130.

The liquid transport system 2190 may include a harness 2230 for attaching conduits 2190A and 2190B to the chassis 2110 of the data processing system or the communication system. Disposed within liquid transport system 2190 and within the harness 2230 are a series of liquid switches or interconnects 2200; one for each slot 2120 in the system 2100 which will receive card(s) 2130 having heat transfer system(s) 2180 thereon. The liquid switches 2200 may be any one of a number of different types available. Each switch will have receptacles 2240 for receiving cooled liquid from conduit 2190A and transferring heated liquid to conduit 2190B. Each switch shall also have receptacles 2250 for detachably transferring cooled liquid from conduit 2190A to liquid feed 2190C and on to the heat transfer system(s) 2180 on a card 2130 and for detachably transferring heated liquid from the heat transfer systems on such card 2130 on liquid feed 2190D to conduit 2190B. The liquid switch 2200 can then be operated to enable or disable the flow of cooled liquid to and heated liquid from the heat transfer system(s) 2180 on a selected card 2130, thereby permitting the connection to or extraction from the bay 2140 in the backplane or rack 2150 of any card 2130 having heat transfer system(s) 2180 thereon and without having to turn off the system 2100. This mechanism allows additional cards 2130 to be added to the system 2100 on line and for removal of cards 2130 from the system for upgrading, service or repair.

The liquid switch 220 may be configured to allow connection between or detachment from liquid feed conduits 2190C and 2190D and receptacles 2250 only when the liquid switch is in the off position which prevents the flow of liquid from conduits 2190A and 2190B to liquid feed conduits 2190C and 2190B, respectively, and thereby preventing the spillage of liquid therefrom. The receptacles 2250 may be further configured and combined with mating receptacles attached to liquid feed conduits 2190C and 2190D such that liquid in the liquid feed conduits 2190C and 2190D is contained in a closed loop whenever the liquid feed conduits 2190C and 2190D are not connected to a switch 2200. This shall ensure that there is no spillage when disconnecting a card 2130 and will enable the maintenance of the proper volume of liquid in the entire liquid transport system 2190 at all times and irrespective of the number of cards 2130 connected at any one time. The switch 2200 should also be a secure type so as only to permit operation by an authorized technician.

Thus, the present invention has been described herein with reference to a particular embodiment for a particular application. Those having ordinary skill in the art and access to the present teachings will recognize additional modifications, applications, and embodiments within the scope thereof.

It is, therefore, intended by the appended claims to cover any and all such applications, modifications, and embodiments within the scope of the present invention.

What is claimed is:

1. A cooling system for cooling heat-generating components in an electronic system comprising:
one or more circuit cards having one or more heat-generating components disposed thereon;
one or more heat transfer units thermally coupled to one or more heat-generating components, the heat transfer units receiving cooled coolant at an inlet thereof, transferring heat to the cooled coolant from one or more heat-generating components thermally coupled thereto, thereby creating heated coolant, and directing the heated coolant to an outlet thereof;
one or more heat exchange units having an inlet for receiving heated coolant from one or more heat transfer units and for cooling said coolant to provide cooled coolant at an outlet thereof for transportation to the inlets of one or more heat transfer units;
heat transfer unit coolant transport means coupled to inlets and outlets of the heat transfer units;
heat exchange unit coolant transport means coupled to the inlets and outlets of the heat exchange units; and
one or more coolant transport interconnect means operable to enable/disable coolant transportation between the heat transfer unit coolant transport means and the heat exchange unit coolant transport means.

2. The cooling system of claim 1 wherein the coolant transport interconnect means includes a self-sealing means which seals the heat transfer unit coolant transport means when a circuit card is disconnected from the electronic system, thereby preventing spillage of coolant.

3. The cooling system of claim 2 wherein the heat transfer unit coolant transport means for a circuit card is loaded with coolant before the circuit card is connected to the system.

4. The cooling system of claim 1 wherein the coolant transport interconnect means includes a self-sealing means which seals the heat exchange unit coolant transport means when a circuit card is disconnected from the electronic system, thereby preventing spillage of coolant.

5. The cooling system of claim 4 wherein the heat exchange unit coolant transport means is loaded with coolant before circuit cards are connected to the system.

6. The cooling system of claim 1 wherein at least one coolant transport interconnect means includes a switch which can be operated by a system operator to switch on and establish coolant communication between a heat transfer unit transport means and a heat exchange unit transport means and to switch off coolant communication between a heat transfer unit transport means and a heat exchange transport means.

7. The cooling system of claim 1 wherein the heat transfer unit coolant transport means comprises one or more coolant pathways which are fastened to the circuit card.

8. The cooling system of claim 7 wherein the coolant transport interconnect means includes means for coupling to the one or more coolant pathways fastened to the circuit card.

9. The cooling system of claim 1 wherein the heat exchange unit coolant transport means comprises one or more coolant pathways which are harnessed and fastened to the electronic system.

10. The cooling system of claim 1 wherein the coolant transport interconnect means includes means for coupling to the one or more coolant pathways of the heat exchange unit coolant transport means harnessed and fastened to the electronic system.

11. The cooling system of claim 1 disposed within the housing of the electronic system.

12. The cooling system of claim 1 wherein the electronic system is a data processing system.

13. The cooling system of claim 1 wherein the electronic system is a communication system.

14. The cooling system of claim 1 wherein the electronic system is a server.

15. The cooling system of claim 1 wherein the electronic system is a system having one or more processors.

16. The cooling system of claim 1 wherein at least one heat generating component is an optical device.

17. A method of cooling heat-generating components in an electronic system having one or more circuit cards with one or more heat-generating components disposed thereon; one or more heat transfer units thermally coupled to one or of the more heat-generating components, the heat transfer units receiving cooled coolant at an inlet thereof, transferring heat to the cooled coolant from one or more heat-generating components, thereby creating heated coolant, and directing the heated coolant to an outlet thereof; one or more heat exchange units having an inlet for receiving heated coolant from one or more heat transfer units and for cooling said coolant to provide cooled coolant at an outlet thereof for transportation to the inlets of one or more heat transfer units; heat transfer unit coolant transport means coupled to inlets and outlets of heat transfer units; heat exchange unit coolant transport means coupled to the inlets and outlets of the heat exchange units; and one or more coolant transport interconnect means operable to enable/disable coolant transportation between the heat transfer unit coolant transport means and the heat exchange unit coolant transport means; the method comprising the steps of:
establishing coolant communication between the heat transfer unit transport means and the heat exchange unit transport means by operating the interconnect means.

18. The method of claim 17 wherein the coolant transport interconnect means is operated by connecting a circuit card to the electronic system.
